(19) United States
(12) Patent Application Publication
(10) Pub. No.: US 2025/0371237 A1
(43) Pub. Date: Dec. 4, 2025

(54) SHARED TOP LEVEL DIGITAL-TO-ANALOG PARALLEL DATA BUS

(71) Applicant: STMicroelectronics International N.V., Geneva (CH)

(72) Inventors: Santi Carlo Adamo, Aci Castello (IT); Sandor Petenyi, Lysa nad Labem (CZ); Ignazio Cala', Siracusa (IT); Roberto Lanza, Catania (IT)

(21) Appl. No.: 18/731,750

(22) Filed: Jun. 3, 2024

(51) Int. Cl. G06F 30/373

(52) U.S. Cl. CPC G06F 30/373

(57) ABSTRACT

An integrated circuit includes N analog circuit blocks, a bidirectional M-bit parallel data bus coupled to each of the N analog circuit blocks, an external data port, and an interface circuit coupled to the external data port and the bidirectional M-bit parallel data bus. Each analog block includes at most X data registers. The interface circuit includes an analog block selection output, a register selection output, and a mode selection output, each coupled to each of the N analog circuit blocks. The analog block selection output is configured to select an analog block using at most N signals. The register selection output is configured to select a register using at most X signals. The mode selection output is configured to control the direction of data flow between the analog blocks and the interface circuit on the data bus.

### TECHNICAL FIELD

The present invention relates generally to top level signal routing in integrated circuits, and, in particular embodiments, to structures of integrated circuits that include top level signal routing between a digital core and multiple analog circuit blocks, and methods of operation thereof.

### BACKGROUND

Modern integrated circuits can include multiple circuit blocks to provide additional functionality. Broadly speaking, integrated circuits may include some combination of digital circuit blocks (e.g., digital logic) and analog circuit blocks (e.g., filters, rectifiers, amplifiers, oscillators, regulators, and others). Digital circuits (such as a digital core) are often used to control various aspects of analog circuitry (e.g., one or more analog circuit blocks, which may have a specific function and occupy a well-defined area of the integrated circuit; analog IPs). For example, data registers (digital circuitry) can be used to provide configuration data to analog circuit blocks. Values may be loaded into the data registers from an external source (e.g., a user, process engineer, etc.) or from internal memory, such as nonvolatile memory (NVM).

When the number and complexity of analog circuit blocks becomes high, the number of data registers to configure and trim analog blocks grows rapidly. A single digital core may be used to control all of the analog circuit blocks in many integrated circuits. Some examples include power management integrated circuits (PMIC), electronic fuse (E-Fuse) circuits, hot swap controllers, and others that can store user and trimming parameters in an NVM load the configuration data into registers at start-up (e.g., using a macro). Since the NVM and all of the registers (e.g., a large number), are in digital core, an undesirable amount of routing area is required to output the total number of user and trimming bits (i.e., hundreds or thousands of bits) as a wire bundle from the digital core to the analog circuit blocks. Therefore, integrated circuits with top level signal routing between a digital core and multiple analog circuit blocks that uses less chip area and/or fewer signals is desirable.

### SUMMARY

In accordance with an embodiment of the invention, an integrated circuit includes N analog circuit blocks, a bidirectional M-bit parallel data bus coupled to each of the N analog circuit blocks, an external data port configured to receive data external to the integrated circuit, and an interface circuit coupled to the external data port and the bidirectional M-bit parallel data bus. The N analog circuit blocks each include at most X data registers. The interface circuit includes an analog circuit block selection output, a register selection output, and a mode selection output. The analog circuit block selection output is coupled to each of the N analog circuit blocks and is configured to select an analog circuit block using at most N signals. The register selection output is coupled to each of the N analog circuit blocks and is configured to select a data register using at most X signals. The mode selection output is coupled to each of the N analog circuit blocks and is configured to control the direction of data flow between the N analog circuit blocks and the interface circuit on the bidirectional M-bit parallel data bus.

In accordance with another embodiment of the invention, an integrated circuit includes N analog circuit blocks, a bidirectional M-bit parallel data bus coupled to each of the N analog circuit blocks, an external data port configured to receive data external to the integrated circuit, an interface circuit coupled to the external data port and the bidirectional M-bit parallel data bus, and a non-volatile memory coupled to the interface circuit. The N analog circuit blocks each include at most X data registers. The interface circuit includes an analog circuit block selection output, a register selection output, and a mode selection output. The analog circuit block selection output is coupled to each of the N analog circuit blocks and is configured to select an analog circuit block using at most N signals. The register selection output is coupled to each of the N analog circuit blocks and is configured to select a data register using log₂X signals. The register selection output is a log₂X-bit register address coupled to each of the N analog circuit blocks. The mode selection output is coupled to each of the N analog circuit blocks and is configured to control the direction of data flow between the N analog circuit blocks and the interface circuit on the bidirectional M-bit parallel data bus. The non-volatile memory is configured to read and write configuration data to and from selected data registers of selected analog circuit blocks over the bidirectional M-bit parallel data bus.

In accordance with still another embodiment of the invention, a method of transferring configuration data between an interface circuit of an integrated circuit and a data register of an analog circuit block includes selecting a first analog circuit block from N analog circuit blocks of the integrated circuit by asserting at most N block selection signals at an analog circuit block selection output of the interface circuit, selecting a first data register from at most X data registers of the first analog circuit block by asserting at most X block selection signals at a register selection output of the interface circuit, enabling a data output of the interface circuit coupled to a bidirectional M-bit parallel data bus to transmit first configuration data over the bidirectional M-bit parallel data bus to the first analog circuit block, and writing the first configuration data from the bidirectional M-bit parallel data bus to the first data register by asserting a write enable signal at a mode selection output of the interface circuit. The write enable signal is asserted after enabling the data output of the interface circuit. The analog circuit block selection output, the register selection output, and the mode selection output of the interface circuit are each coupled to each of the N analog circuit blocks. The bidirectional M-bit parallel data bus is also coupled to each of the N analog circuit blocks.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 schematically illustrates an example integrated circuit that includes a digital logic circuit coupled to analog circuitry using a parallel bus that is shared between multiple analog circuit blocks of the integrated circuit in accordance with embodiments of the invention;

FIG. 2 schematically illustrates another example integrated circuit that includes a digital logic circuit coupled to analog circuitry using a parallel bus that is shared between multiple analog circuit blocks of the integrated circuit where logic of each analog circuit block includes a tristate buffer in accordance with embodiments of the invention;

FIG. 3 illustrates a conventional integrated circuit that uses a data wire for every bit of every data register associated with the analog circuit blocks resulting hundreds or thousands of data wires carrying signals between the analog circuit blocks and top-level digital logic;

FIG. 4 schematically illustrates an example integrated circuit with digital-to-analog signals that use an individual bit for selecting each analog circuit block as well as an individual bit for selecting each data register in accordance with embodiments of the invention;

FIG. 5 schematically illustrates an example integrated circuit with digital-to-analog signals that use an individual bit for selecting each analog circuit block and a base 2 register address to select each data register in accordance with embodiments of the invention;

FIG. 6 schematically illustrates an example integrated circuit with digital-to-analog signals that use a base 2 block address to select each analog circuit block and a base 2 register address to select each data register in accordance with embodiments of the invention;

FIG. 7 illustrates a timing diagram of an example write procedure during which data provided to the shared parallel data bus by an interface circuit is written to a selected data register of a selected analog circuit block using a write enable pulse in accordance with embodiments of the invention;

FIG. 8 illustrates a timing diagram of an example read procedure during which data provided to the shared parallel data bus by a selected data register of a selected analog circuit block is read by an interface circuit using a read pulse in accordance with embodiments of the invention;

FIG. 9 illustrates a timing diagram of an example NVM read procedure during which configuration data read from the NVM and sequentially provided to the shared parallel data bus by an interface circuit is written to selected data registers of selected analog circuit blocks in accordance with embodiments of the invention;

FIG. 10 illustrates a timing diagram of an example NVM write procedure during which configuration data sequentially provided to the shared parallel data bus by selected data registers of selected analog circuit blocks is read by the interface circuit so that it may then be written into the NVM in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

Integrated circuits that have multiple analog circuit blocks (e.g., integrated circuits developed using an “analog on top” approach that incorporate multiple analog IPs), such as PMICs (power management ICs), E-Fuse (electronic fuse), and hot swap controllers may load parameters (e.g., user, trimming, configuration, design-for-test (DFT), etc.) into a large number of data registers in a digital core from an NVM (nonvolatile memory) at start-up. For example, this functionality may be placed as a macro on top layout. Since all of the configuration data for the analog circuit blocks is in registers in the digital core, there are a large number of output signals (i.e., at least equal to the number of user and trimming bits), that go around the die to be connected to the corresponding analog circuit blocks.

The resulting wire bundle can be huge for complex products (e.g., PMIC and E-fuse, but also others) and has a proportionally huge impact on top level routing and a large amount of area in the device is wasted. This imposes undesirable costs in terms of layout effort and die size of the device. Additionally, the large numbers of signal outputs from the digital core undesirably reduces row utilization, and the chip area of the digital core itself is increased.

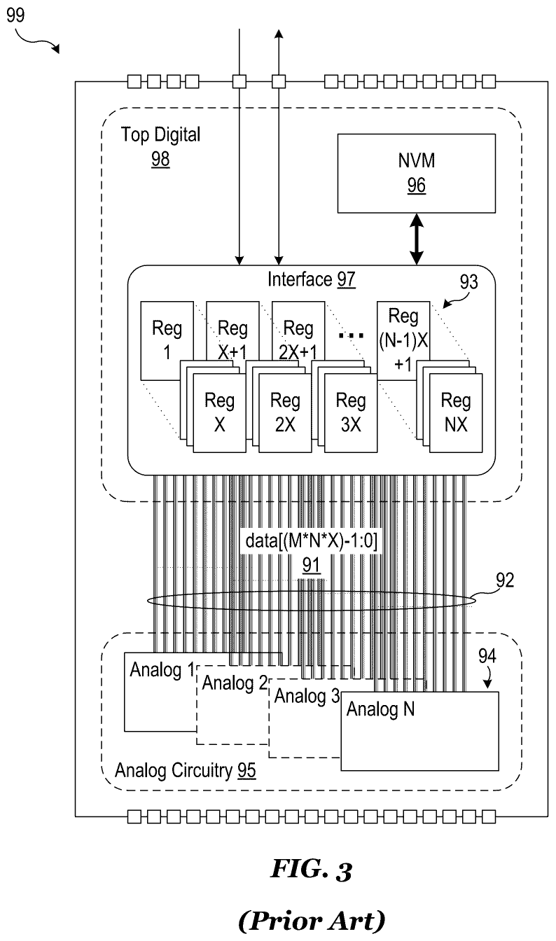

FIG. 3 illustrates a conventional integrated circuit 99 that has a top-level digital logic block 98 and analog circuitry 95 including N analog circuit blocks 94 (N being greater than one, but often much higher). A conventional interface circuit 97 has nonvolatile memory 96 connected to sets of data registers. At most X data registers are associated with each of the N analog circuit blocks 94. For example, each of the N analog circuit blocks 94 may have up to X corresponding registers for a maximum of N*X data registers 93.

The data stored in the N*X data registers 93 is output from the top-level digital logic block 98 to the analog circuitry 95 using conventional digital-to-analog signals 92, the number of which may be quite large. Specifically, if the data registers each have M bits, the conventional digital-to-analog signals 92 have at least M*N*X data wires 91, a number that can quickly become undesirably large (e.g., hundreds or thousands of data wires). For example, even considering only 8-bit registers, 4 analog circuit blocks, and 16 registers per analog circuit block (M=8, N=4, X=16), the conventional digital-to-analog signals 92 require 512 data wires. Of course, this number may be and often is even higher. This causes high wire congestion in the top level routing of the conventional integrated circuit 99 and occupies undesirably large regions of the chip area.

In accordance with embodiments herein described, the invention proposes to reduce the number of data wires between a digital logic circuit and analog circuitry in an integrated circuit using a shared parallel data bus implemented at the top routing level of the integrated circuit. The parallel data bus is bidirectional and has a number of parallel data wires equal to the register size (or largest register size) of sets of data registers included in multiple analog circuit blocks of the analog circuitry. Each set of data registers is associated with and included in a corresponding analog circuit block of the analog circuitry in the integrated circuit. The desired analog circuit block is selected using an analog circuit block selection signal (e.g., individual selection bits or a multibit address) while the desired register is selected using a register selection signal (which also may use individual selection bits or a multibit address). A mode selection signal is used to indicate whether data is being written to or read from the selected register of the selected analog circuit block.

The embodiments described herein may advantageously reduce the number of signal wires (e.g., from hundreds/thousands to tens) routed between a digital logic circuit of an integrated circuit (e.g., a digital core) and multiple analog circuit blocks (e.g., analog IPs) compared to conventional integrated circuits (i.e., that have the number of analog circuit blocks, number of registers, and register sizes; the same number of configuration bits). For example, an embodiment integrated circuit that has 8-bit registers, 4 analog circuit blocks, and 16 registers per analog circuit block (M=8, N=4, X=16) may advantageously use at most M+N+X=28 signal wires (plus one or more mode selection wires, such as write enable, read enable, reset, etc.) while conventional integrated circuits having M=8, N=4, and X=16 require 512 or more. The reduction in signal wires may advantageously result in lower routing area and lower die size while maintaining the same number of register bits (e.g., NVM user/trim register bits).

The top-level routing architecture may be usable in devices with an internal memory (e.g., an NVM) is present and/or an external input/output. For example, communication between an interface circuit and an NVM or an external input/output may use the inter-integrated circuit (I2C) protocol, but other protocols are of course possible. Analog circuit block (e.g., analog IP) features may be programmed by users, engineers, etc. using the external input/output. Configuration data (e.g., settings) may be stored in the internal memory. The interface circuit may use the shared parallel bus to communicate the configuration data to the analog circuit block.

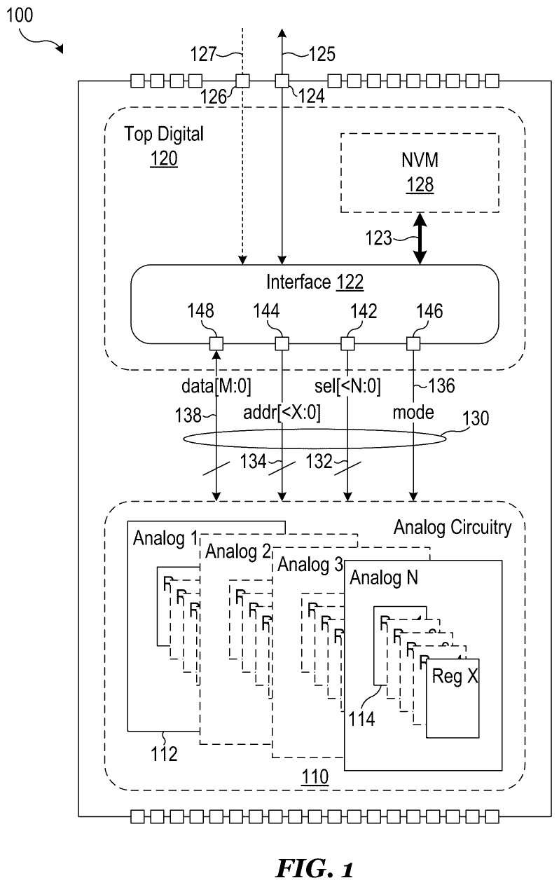

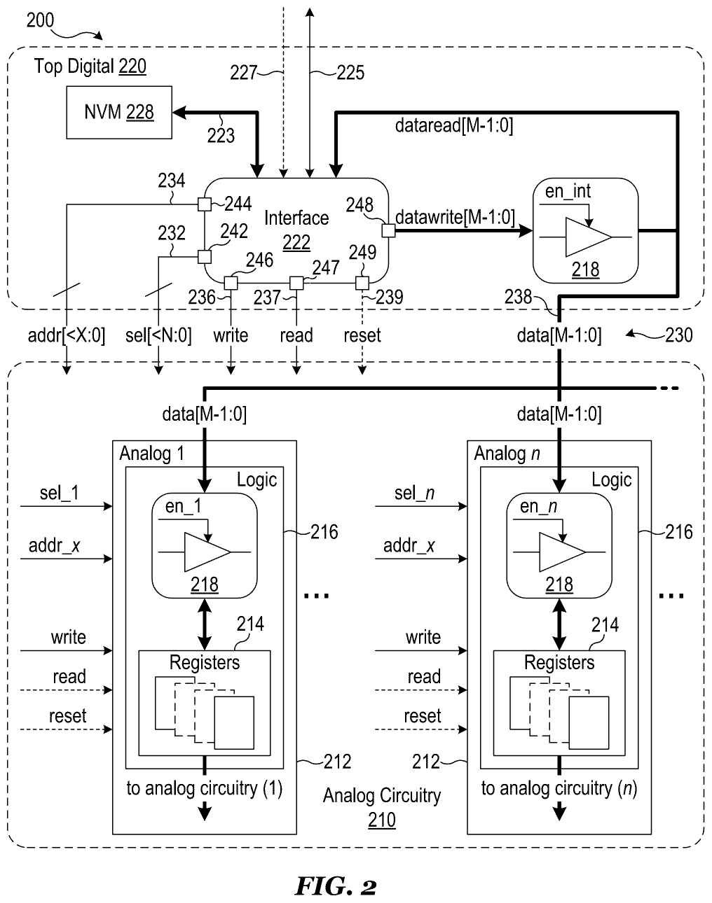

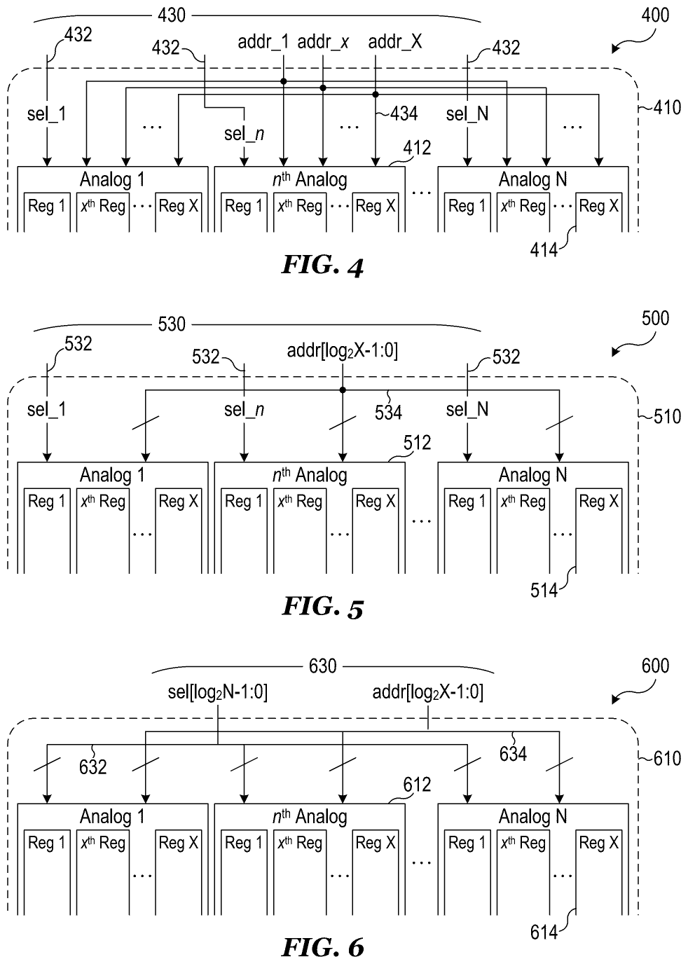

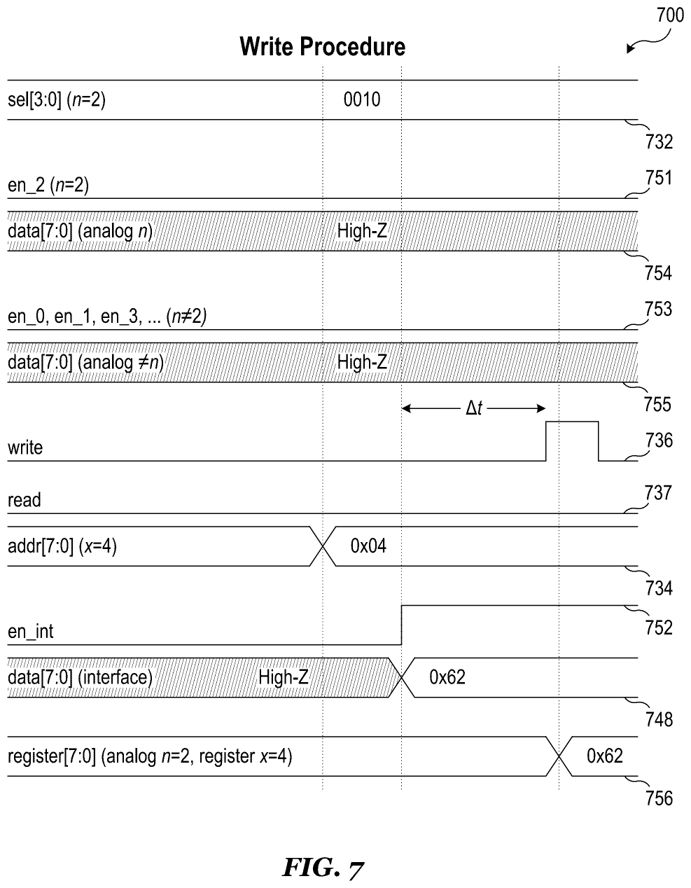

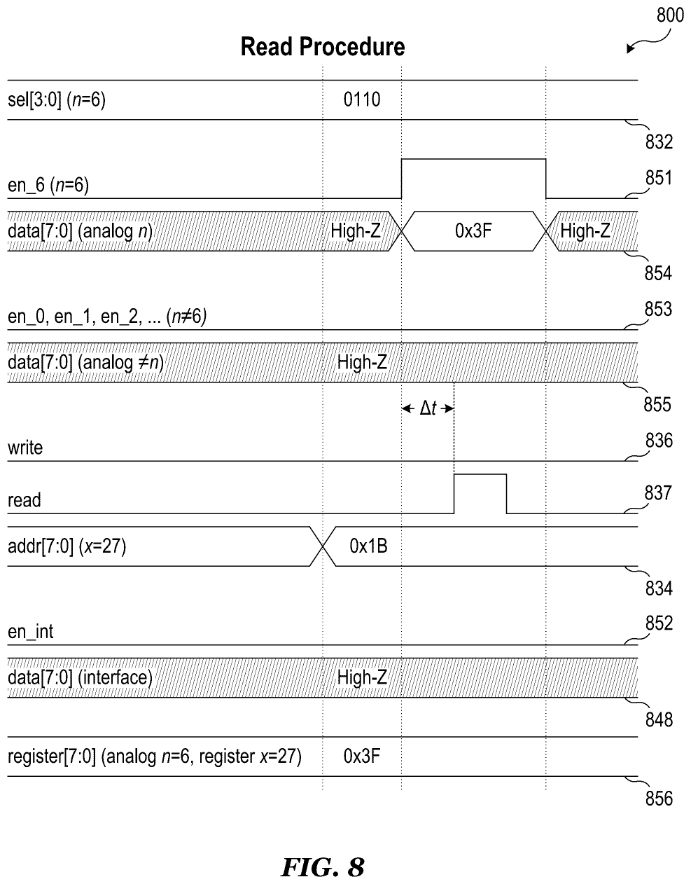

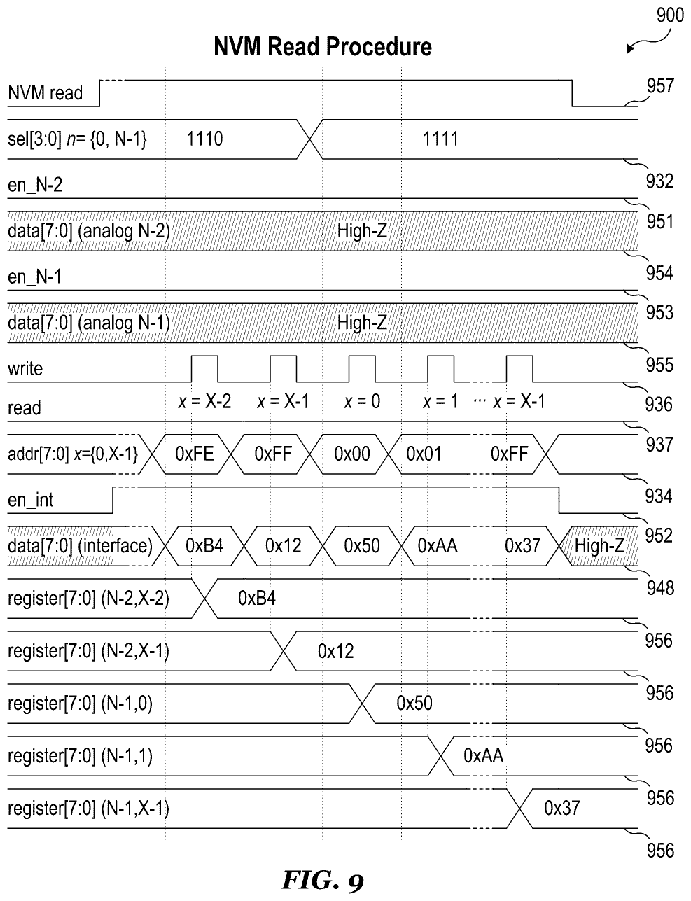

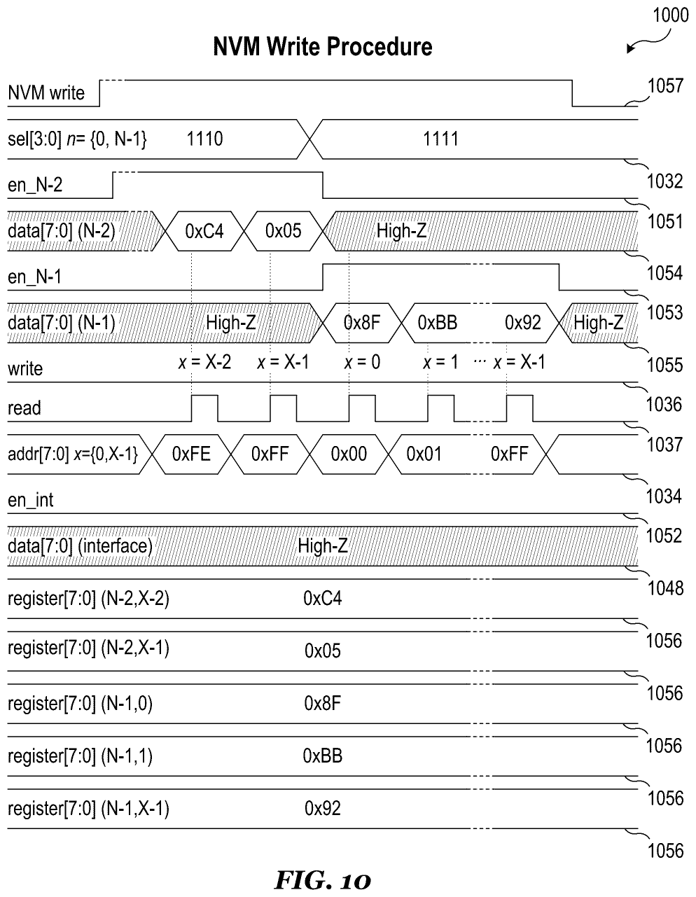

Embodiments provided below describe various integrated circuits with top-level signal routing between a digital logic circuit and multiple analog circuit blocks, and in particular, integrated circuits that include a parallel data bus that is shared by the analog circuit blocks. The following description describes the embodiments. FIG. 1 is used to describe an example integrated circuit with a shared parallel data bus. Another example integrated circuit with multiple analog circuit blocks that each have a tristate buffer is described using FIG. 2. Three more example integrated circuits with different addressing implementations are described using FIGS. 4-6. An example write procedure is described using FIG. 7. An example read procedure is described using FIG. 8. FIGS. 9 and 10 are used to describe an example NVM read procedure and an example NVM write procedure, respectively.

FIG. 1 schematically illustrates an example integrated circuit that includes a digital logic circuit coupled to analog circuitry using a parallel bus that is shared between multiple analog circuit blocks of the integrated circuit in accordance with embodiments of the invention.

Referring to FIG. 1, an integrated circuit 100 includes analog circuitry 110 coupled to a digital logic circuit 120 (e.g., a top-level digital logic circuit, such as a digital core) using digital-to-analog signals 130. The analog circuitry 110 includes multiple analog circuit blocks 112. In various embodiments, the analog circuit blocks 112 are analog devices (e.g., analog IPs), such as oscillator circuits, bandgap voltage reference circuits, voltage regulator circuits (e.g., a linear voltage regulator, such as low-dropout (LDO regulator), converter circuits (e.g., DC-DC, AC-DC, DC-AC, AC-AC), and others.

Each of the analog circuit blocks 112 includes a set of data registers 114 that are configured to store data that controls various behavioral aspects of the respective analog circuit block (i.e., configuration data). While each of the analog circuit blocks 112 may be a self-contained analog circuit with defined functionality occupying a contiguous region (e.g., a block) of the layout area (e.g., an analog IP), this is not a requirement. For example, each analog circuit block may be simply be any physical or logical grouping of analog components that use the data in a single set of data registers 114. That is, whereas in many applications it may be advantageous for each of the analog circuit blocks 112 to be a contiguous block (e.g., for routing efficiency within the analog circuitry 110), there may be applications where various analog components of two or more analog circuit blocks are physically interspersed within the analog circuitry 110.

The digital logic circuit 120 is configured for bidirectional communication with the analog circuit blocks 112 using a parallel data bus 138 that is shared by all of the analog circuit blocks 112. Specifically, the parallel data bus 138 has a data bus size M (i.e., the number of data wires carrying signals in parallel) so that the parallel data bus 138 is an M-bit parallel data bus. The parallel data bus 138 is shared by all of the analog circuit blocks 112 in the sense that only a single bundle of M data wires are routed (i.e., at the top level) between the digital logic circuit 120 and the analog circuitry 110 and connection is made from the parallel data bus 138 to each of the analog circuit blocks 112 at or near the respective analog circuit block. Each set of data registers 114 is served by the connection of the parallel data bus 138 to associated analog circuit block.

The digital logic circuit 120 includes an interface circuit 122 configured to manage data communication between the analog circuitry 110 and external and/or internal sources. For example, the analog circuitry 110 includes an external data port 124 configured to receive external data 125 (data received from a source external to the integrated circuit 100) that may be loaded into one or more of the data registers 114 of various analog circuit blocks 112. The external data port 124 may be configured for serial communication, such as using the I2C protocol with the external data 125 being a serial data (SDA) port. To that end, the integrated circuit 100 may also include an optional external clock port 126 configured to receive an optional external clock signal 127 (e.g., a serial clock line (SCL) used to clock the SDA signal).

The digital logic circuit 120 may also include internal memory, such as an optional nonvolatile memory 128, which may be configured to communicate with the interface circuit 122 using the same protocol as the external data port 124 (e.g., the I2C serial data communication protocol) or a different protocol. Specifically internal data 123 may be read from and written to the optional nonvolatile memory 128, when included. Of course, there is no limitation on the type of communication implementation for the external data or internal storage communication capabilities of the interface circuit 122. One or both may implement a different communication protocol than I2C. For example, the external data 125 may use a different form of serial data communication while the optional nonvolatile memory 128 may use a form of parallel data communication.

The parallel data bus 138 is connected to the interface circuit 122 at a data input/output 148. In order to share the parallel data bus 138, additional signal wires are included in the digital-to-analog signals 130 that are configured to select a desired analog circuit block and desired data register within the desired analog circuit block. For example, a block selection signal 132 is coupled to an analog circuit block selection output 142 of the interface circuit 122 and is configured to select desired analog circuit block.

The number of signal wires in the block selection signal 132 is capped by the number of analog circuit blocks 112 and may be much lower. For example, if the number of data registers 114 is N, then the block selection signal 132 has at most N signal wires (i.e., if a signal wire carrying a single toggle bit is used for each of the N analog circuit blocks 112). However, an address system may also be used, allowing the number of signal wires in the block selection signal 132 to be log₂(N). For example, sixteen analog circuit blocks (N=16) could be uniquely addressed by a 4-bit block selection signal 132 (log₂(16)=4).

In order to select the desired data register in a set of data registers 114 associated with a selected analog circuit block, a register selection signal 134 is coupled to a register selection output 144 of the interface circuit 122. The register selection signal 134 is configured to select a desired data register. Similar to the block selection signal 132, the number of signal wires in the register selection signal 134 is capped, this time by the maximum number of data registers 114 in any set of data registers 114 in the analog circuitry 110. For example, if the maximum number of data registers in any set of the data registers 114 is X, then the register selection signal 134 has at most X signal wires and the number of signal wires in the register selection signal 134 may be log₂(X) if an address system is used. By way of example, up to 256 data registers per analog circuit block (X=128) could be uniquely addressed by a 8-bit register selection signal 134 (log₂(256)=8).

Each of the data registers 114 has a register size that is at most M bits. That is, in many cases the size of all the data registers 114 may be the same (i.e., equal to M), but in some cases there may be data registers with fewer than M bits. Specifically, since the parallel data bus 138 is configured to read/write data from/to a single selected register of a single selected analog circuit block at a time, the size of the parallel data bus equal to the maximum size of a single data register.

A mode selection signal 136 coupled to a mode selection output 146 of the interface circuit 122 is also included in the digital-to-analog signals 130. The mode selection signal 136 is configured to control the direction of the flow of data on the parallel data bus 138 between the interface circuit 122 and the analog circuit blocks 112 (and may also be configured to control other modes as well). The size and implementation of the mode selection signal 136 may vary based on the number of communication modes and the desired functionality of the various modes.

In one embodiment, the mode selection output 146 consists of a single bit (the mode selection signal 136) coupled to each of the analog circuit blocks 112 that is configured to toggle the mode of the selected analog circuit block between write mode and read mode. In other embodiments, the mode selection output 146 comprises a write enable signal and a read enable signal (together forming at least part of the mode selection signal 136) that are both coupled to each of the analog circuit blocks 112. In this specific example, the write enable signal is configured to enable write mode of the selected analog circuit block and the read enable signal is configured to enable read mode of the selected analog circuit block.

In some cases, the digital-to-analog signals 130 may be a single signal wire that controls whether the interface circuit 122 is in read mode (e.g., logical ‘0’) or write mode (e.g., logical ‘1’). However, in some cases, such as when timing is important for both read mode and write mode, two signal wires may be used (a write enable signal and a read enable signal). Further, additional modes may also be included as well as additional signal wires, such as a reset signal (e.g., to reset the data registers before loading (or reloading/updating/etc.) configuration data into the data registers).

As may be determined from the above discussion, the digital-to-analog signals 130 have one or more orders of magnitude fewer signal wires than conventional analog-to-digital signals routed between a top-level digital logic block and multiple analog circuit blocks. Specifically, for 16 analog circuit blocks, each containing up to 256 8-bit data registers (M=8, N=16, X=256), the digital-to-analog signals 130 have less than M+N+X=280 signal wires (plus one or more mode selection wires) and can have as few as M+log₂(N)+log₂(X)+1 mode selection bit=21 signal wires. In contrast conventional signal routing would require M*N*X=32,768 data wires.

The improved top-level signal routing of the digital-to-analog signals 130 may be applied in various systems. For example, the integrated circuit 100 may be any integrated circuit that controls multiple analog circuit blocks (e.g., analog IPs) with a single digital logic circuit using top-level signal routing. In one embodiment, the integrated circuit 100 is a PMIC (power management IC). In another embodiment, the integrated circuit 100 is an E-Fuse circuit. In still another embodiment, the integrated circuit 100 is a hot swap controller. Of course, the integrated circuit 100 may also be other types of circuits that include analog functionality.

FIG. 2 schematically illustrates another example integrated circuit that includes a digital logic circuit coupled to analog circuitry using a parallel bus that is shared between multiple analog circuit blocks of the integrated circuit where logic of each analog circuit block includes a tristate buffer in accordance with embodiments of the invention. The integrated circuit of FIG. 2 may be a specific implementation of other integrated circuits described herein such as the integrated circuit of FIG. 1, for example. Similarly labeled elements may be as previously described.

Referring to FIG. 2, an integrated circuit 200 includes analog circuitry 210 coupled to a digital logic circuit 220 using digital-to-analog signals 230. As before, the analog circuitry 210 includes multiple analog circuit blocks 212 that each includes a set of data registers 214 configured to store data for controlling various behavioral aspects of the respective analog circuit block (i.e., configuration data).

It should be noted that here and in the following a convention has been adopted for brevity and clarity wherein elements adhering to the pattern [x30] where ‘x’ is the figure number may be related implementations of digital-to-analog signals in various embodiments. For example, the digital-to-analog signals 230 may be similar to the digital-to-analog signals 130 except as otherwise stated. An analogous convention has also been adopted for other elements as made clear by the use of similar terms in conjunction with the aforementioned numbering system.

The digital logic circuit 220 is configured for bidirectional communication with the analog circuit blocks 212 using a parallel data bus 238 (an M-bit parallel data bus) that is shared by all of the analog circuit blocks 212. The digital logic circuit 220 includes an interface circuit 222 configured to receive external data 225 to be loaded into (i.e., written to) one or more of the data registers 214 of various analog circuit blocks 212. The interface circuit 222 may also be configured to receive an optional external clock signal 227. In this specific example, the digital logic circuit 220 also includes a nonvolatile memory 228 configured to store internal data 223.

The parallel data bus 238 is connected to the interface circuit 222 at a data output 248. An block selection signal 232 is coupled to an analog circuit block selection output 242 of the interface circuit 222 while a register selection signal 234 is coupled to a register selection output 244 of the interface circuit 222. In this specific example, a write enable signal 236 an a read enable signal 237 (i.e., a specific example of a 2-bit mode selection signal) are coupled to a write output 246 and a read output 247 of the interface circuit 122, respectively. An optional reset signal 239 coupled to an optional reset output 249 may be included in some implementations (such as to reset the data registers 214).

The implementation of the parallel data bus 238 at the interface circuit 222 and the analog circuit blocks 212 may vary. In this specific example, a tristate buffer 218 is included in the digital logic circuit 220 and in a logic circuit block 216 of each of the analog circuit blocks 212. Enable signals (an interface enable signal en_int, en_1, en_2, etc.) can be used to assert the data stored in the respective tristate buffer 218 on the parallel data bus 238 at the appropriate time, such as using the write enable signal 236 and the read enable signal 237 in combination with the block selection signal 232 and the register selection signal 234. For example, when not enabled, the output of each tristate buffer 218 may have a high impedance (i.e., high Z) allowing the parallel data bus 238 to be used by the selected (i.e., enabled) tristate buffer 218.

FIG. 4 schematically illustrates an example integrated circuit with digital-to-analog signals that use an individual bit for selecting each analog circuit block as well as an individual bit for selecting each data register in accordance with embodiments of the invention. The integrated circuit of FIG. 4 may be a specific implementation of other integrated circuits described herein such as the integrated circuit of FIG. 1, for example. Similarly labeled elements may be as previously described.

Referring to FIG. 4, an integrated circuit 400 includes analog circuitry 410 with N analog circuit blocks 412 that each have a set of data registers 414. The analog circuitry 410 is coupled to a digital-to-analog signals 430, which is a specific implementation of other example digital-to-analog signals described herein (although in this example only a block selection signal 432 and a register selection signal 434 are shown for simplicity).

In this specific example, a single signal wire (i.e., a single toggle bit) is used for both the selection of a desired analog circuit block (using the block selection signal 432) and for the selection of a desired data register within the selected analog circuit block (using the register selection signal 434). As shown only a single signal wire is connected to each of the N analog circuit blocks 412 while all of the X signal wires of the register selection signal 434 are connected to each of the analog circuit blocks 412 (because each analog circuit block has a set of the data registers 414).

Since a signal wire is used for each of the N analog circuit blocks 412 and each of the X data registers 414, the specific example of integrated circuit 400 represents the upper limit for the number of signal wires in the block selection signal 432 (i.e., sel[N-1:0]) and the register selection signal 434 (i.e., addr[X-1:0]) that are routed between the analog circuitry 410 and a digital logic circuit, such as a digital core.

FIG. 5 schematically illustrates an example integrated circuit with digital-to-analog signals that use an individual bit for selecting each analog circuit block and a base 2 register address to select each data register in accordance with embodiments of the invention. The integrated circuit of FIG. 5 may be a specific implementation of other integrated circuits described herein such as the integrated circuit of FIG. 1, for example. Similarly labeled elements may be as previously described.

Referring to FIG. 5, an integrated circuit 500 includes analog circuitry 510 with N analog circuit blocks 512 that each have a set of data registers 514. The analog circuitry 510 is coupled to a digital-to-analog signals 530, which is a specific implementation of other example digital-to-analog signals described herein (although in this example only a block selection signal 532 and a register selection signal 534 are shown for simplicity).

In this specific example, a single signal wire (i.e., a single toggle bit) is used for the selection of a desired analog circuit block (using the block selection signal 532) while a base 2 register address is used for the selection of a desired data register within the selected analog circuit block (using the register selection signal 534). Similar to the integrated circuit 400, only a single signal wire is connected to each of the N analog circuit blocks 512. However, while all of the signal wires of the register selection signal 534 are connected to each of the analog circuit blocks 512, the register selection signal 534 has fewer than X signal wires due to the use of an address system.

The specific example of integrated circuit 500 represents a middle ground for the number of signal wires in the block selection signal 532 because a signal wire is used for each of the N analog circuit blocks 512 (i.e., sel[N-1:0]), but only log₂(X) wires are used for the register selection signal 534 (i.e., addr[log₂(X)-1:0]). Therefore, less than the maximum number of signal wires are routed between the analog circuitry 510 and a digital logic circuit, such as a digital core.

FIG. 6 schematically illustrates an example integrated circuit with digital-to-analog signals that use a base 2 block address to select each analog circuit block and a base 2 register address to select each data register in accordance with embodiments of the invention. The integrated circuit of FIG. 6 may be a specific implementation of other integrated circuits described herein such as the integrated circuit of FIG. 1, for example. Similarly labeled elements may be as previously described.

Referring to FIG. 6, an integrated circuit 600 includes analog circuitry 610 with N analog circuit blocks 612 that each have a set of data registers 614. The analog circuitry 610 is coupled to a digital-to-analog signals 630, which is a specific implementation of other example digital-to-analog signals described herein (although in this example only a block selection signal 632 and a register selection signal 634 are shown for simplicity).

In this specific example, base 2 addressing schemes are used for both the selection of a desired analog circuit block (using the block selection signal 632) and for the selection of a desired data register within the selected analog circuit block (using the register selection signal 634). All of the log₂(N) signal wires of the block selection signal 632 and all of the log₂(X) signal wires of the register selection signal 634 are connected to each of the N analog circuit blocks 612.

The specific example of integrated circuit 600 represents a lower limit for the number of signal wires in the block selection signal 632 because only log₂(N) signal wires are used for the N analog circuit blocks 612 (i.e., sel[log₂(N)-1:0]) and only log, (X) wires are used for the register selection signal 634 (i.e., addr[log₂(X)-1:0]). This is of course assuming that each signal wire can only represent 2 states (base 2). If signaling schemes with signal wires that represent more than 2 states were able to be used, the number could go even lower.

FIG. 7 illustrates a timing diagram of an example write procedure during which data provided to the shared parallel data bus by an interface circuit is written to a selected data register of a selected analog circuit block using a write enable pulse in accordance with embodiments of the invention. The procedure of FIG. 7 may be used to transfer data between an interface circuit and selected registers of selected analog circuit blocks for any of the integrated circuits described herein such as the integrated circuit of FIG. 1, for example. Similarly labeled elements may be as previously described.

Referring to FIG. 7, a write procedure 700 is graphically represented by a timing diagram that includes various signals and states of digital-to-analog signals of an integrated circuit as described herein. During the write procedure 700, configuration data is transferred data between an interface circuit of an integrated circuit and a data register of an analog circuit block by selecting an analog circuit block from N analog circuit blocks of the integrated circuit. This is accomplished in by asserting at most N block selection signals at an analog circuit block selection output of the interface circuit coupled to each of the N analog circuit blocks. In this specific example a base 2 address system is used for block selection signal 732 (which here is 0010 or n=2).

A data register is selected from a set of X data registers (or less than X if the selected analog circuit block has less than the maximum number of data registers) of the selected analog circuit block by asserting at most X block selection signals at a register selection output of the interface circuit coupled to each of the N analog circuit blocks. Here, a base 2 address system is used for register selection signal 734 (which provided as 0x04 or x=4 by way of example).

The data output 748 of the interface circuit is then enabled using an interface enable signal 752 (e.g., en_int is brought high) and configuration data (0x62) from the interface circuit is transmitted over the parallel data bus (e.g., a bidirectional M-bit parallel data bus). Prior to enabling the data output 748, the data output may be maintained in a high impedance (high-Z) state. Since the selected block output 754 and the unselected block outputs 755 are not used during the write procedure 700, the selected block enable signal 751 and the unselected block enable signals 753 remain in the disabled state (e.g., logical ‘0’) so that the selected block output 754 and the unselected block outputs 755 stay in the high-Z state.

After a sufficient amount of time Δt, a write enable signal 736 (i.e., a signal coupled to a mode selection output of the interface circuit) is pulsed to write the configuration data to the selected data register 756 of the selected analog circuit block (here, the 4^{th} register of the 2^{nd} analog circuit block). In this example, a read enable signal 737 is also shown, but it is maintained in the disabled state for the write procedure 700.

FIG. 8 illustrates a timing diagram of an example read procedure during which data provided to the shared parallel data bus by a selected data register of a selected analog circuit block is read by an interface circuit using a read pulse in accordance with embodiments of the invention. The procedure of FIG. 8 may be used to transfer data between an interface circuit and selected registers of selected analog circuit blocks for any of the integrated circuits described herein such as the integrated circuit of FIG. 1, for example. Similarly labeled elements may be as previously described.

Referring to FIG. 8, a read procedure 800 is graphically represented by a timing diagram that includes various signals and states of digital-to-analog signals of an integrated circuit as described herein. During the read procedure 800, configuration data is transferred data between an interface circuit of an integrated circuit and a data register of an analog circuit block by selecting an analog circuit block from N analog circuit blocks of the integrated circuit. This is accomplished in by asserting at most N block selection signals at an analog circuit block selection output of the interface circuit coupled to each of the N analog circuit blocks. In this specific example a base 2 address system is used for block selection signal 832 (which here is 0110 or n=6).

A data register is selected from a set of X data registers (or less than X if the selected analog circuit block has less than the maximum number of data registers) of the selected analog circuit block by asserting at most X block selection signals at a register selection output of the interface circuit coupled to each of the N analog circuit blocks. Here, a base 2 address system is used for register selection signal 834 (which provided as 0x1B or x=27 by way of example).

The data output (selected block output 854) of the selected analog circuit block (here, the 6^{th} register of the 27^{th} analog circuit block) is then enabled using a selected block enable signal 851 (e.g., en_6 is brought high) and configuration data (0x3F) from the selected data register 856 of the selected analog circuit block is transmitted over the parallel data bus (e.g., a bidirectional M-bit parallel data bus). Prior to enabling the selected block output 854, the data output may be maintained in a high-Z. Since the data outputs of the interface circuit and the unselected analog circuit blocks (data output 848 and unselected block outputs 855) are not used during the read procedure 800, the interface enable signal 852 and the unselected block enable signals 853 remain in the disabled state (e.g., logical ‘0’) so that the data output 848 and unselected block outputs 855 stay in the high-Z state.

After a sufficient amount of time, Δt, a read enable signal 837 (i.e., a signal coupled to a mode selection output of the interface circuit) is pulsed to read the configuration data from the parallel data bus (e.g., to the interface circuit to output externally or store internally in the nonvolatile memory of the integrated circuit). In this example, a write enable signal 836 is also included, but it is maintained in the disabled state for the read procedure 800.

FIG. 9 illustrates a timing diagram of an example NVM read procedure during which configuration data read from the NVM and sequentially provided to the shared parallel data bus by an interface circuit is written to selected data registers of selected analog circuit blocks in accordance with embodiments of the invention. The procedure of FIG. 9 may be used to transfer data between an interface circuit and selected registers of selected analog circuit blocks for any of the integrated circuits described herein such as the integrated circuit of FIG. 1, for example. Similarly labeled elements may be as previously described.

Referring to FIG. 9, an NVM read procedure 900 is graphically represented by a timing diagram that includes various signals and states of digital-to-analog signals of an integrated circuit as described herein. The NVM read procedure 900 is similar to previously described procedures in that configuration data is transferred data between an interface circuit of an integrated circuit and a data register of an analog circuit block by selecting an analog circuit block from N analog circuit blocks of the integrated circuit. Specifically, the NVM read procedure 900 is similar to the write procedure 700 in that during the NVM read procedure 900, configuration data that will be written into multiple data registers of the N analog circuit blocks (e.g., many data registers, and in some cases all data registers of the analog circuit blocks, such as at startup, using a macro, for example).

The NVM read procedure 900 may be enabled using a NVM read enable signal 957, such as by bringing the NVM read enable signal 957 to a logical ‘1’ value (as shown). In various embodiments, when the NVM read enable signal 957 is enabled, the interface circuit is configured to sequentially read configuration data from internal memory (here, an NVM, but of course other types of internal memory may be used) and write the data to the desired data registers of the analog circuit blocks. For example, the interface circuit may read the configuration data using the I2C protocol. In one embodiment, the NVM read procedure 900 is configured to read all the available configuration data stored in the NVM, which may include data for all of the data registers of the analog circuit blocks (e.g., to initialize or reset the integrated circuit). However, the data registers that are written to during the NVM read procedure 900 is not limited to a specific number of order. Additional functionality may be included to specify a subset of the data registers of the analog block (such as all the registers of a specific analog circuit block, only the registers that have been flagged as updated during a certain period of time, etc.).

For each data register written to during the NVM read procedure 900, the interface circuit reads configuration data from the NVM so that it is available at a data output 948 of the interface circuit (e.g., at a tristate buffer, shown here as the first configuration data at the data output 948, which is 0xB4). This configuration data is associated with a specific data register of a specific analog circuit block. Similar to the write procedure 700, the specific analog circuit block is selected by asserting at most N block selection signals at an analog circuit block selection output of the interface circuit coupled to each of the N analog circuit blocks. For the first two configuration data, the base 2 block address that is asserted as block selection signal 932 is 1110 or n=14 and is changed (e.g., advanced) to 1111 or n=15 for the last three (shown) configuration data.

Data registers are selected from the set of X data registers corresponding to the currently selected analog circuit block (or less than X if the currently selected analog circuit block has less than the maximum number of data registers) by asserting at most X block selection signals at a register selection output of the interface circuit coupled to each of the N analog circuit blocks. Here again, a base 2 address system is used for register selection signal 934 (which is 0xFE or x=254 for the first configuration data, 0xFF or x=255 for the second configuration data, is set to 0x00 of x=0 for the third configuration data as the selected analog circuit clock is advanced, and then continues from there).

At some point after the NVM read enable signal 957 is enabled (but before configuration data is needed on the parallel data bus), the data output 948 of the interface circuit is enabled using an interface enable signal 952 (e.g., en_int is made high) and the configuration data being read from the NVM is available on the parallel data bus. As before, the data output 948 may be maintained in a high-Z state when disabled. The N-2 block enable signal 951 and N-1 block enable signal 953 remain in the disabled state (e.g., logical ‘0’) so that the N-2 block output 954 and the N-1 block output 955 stay in the high-Z state.

A write enable signal 936 is then pulsed with appropriate timing to write the configuration data to the currently selected data register of the selected data registers 956. The read enable signal 937 is maintained in the disabled state since configuration data is being written to the data registers.

These steps are repeated as desired to write additional configuration data into additional data registers. Specifically, the steps of reading additional configuration data from the NVM, selecting a data register that corresponds to the additional configuration data, transmitting the additional configuration data over the parallel data bus, and writing the additional configuration data into the data register may be repeated by successively pulsing the write enable signal 936 (as shown) for a currently selected analog circuit block. Then, these steps may all be repeated as desired for additional selected analog circuit blocks.

FIG. 10 illustrates a timing diagram of an example NVM write procedure during which configuration data sequentially provided to the shared parallel data bus by selected data registers of selected analog circuit blocks is read by the interface circuit so that it may then be written into the NVM in accordance with embodiments of the invention. The procedure of FIG. 10 may be used to transfer data between an interface circuit and selected registers of selected analog circuit blocks for any of the integrated circuits described herein such as the integrated circuit of FIG. 1, for example. Similarly labeled elements may be as previously described.

Referring to FIG. 10, an NVM write procedure 1000 is graphically represented by a timing diagram that includes various signals and states of digital-to-analog signals of an integrated circuit as described herein. The NVM write procedure 1000 is similar to previously described procedures in that configuration data is transferred data between an interface circuit of an integrated circuit and a data register of an analog circuit block by selecting an analog circuit block from N analog circuit blocks of the integrated circuit. Specifically, the NVM write procedure 1000 is similar to the read procedure 800 in that during the NVM write procedure 1000, configuration data is read from multiple data registers of the N analog circuit blocks to the interface circuit (e.g., many data registers, and in some cases all data registers of the analog circuit blocks, such as at startup, using a macro, for example).

The NVM write procedure 1000 may be enabled using an NVM write enable signal 1057, such as by bringing the NVM write enable signal 1057 to a logical ‘1’ value (as shown). In various embodiments, when the NVM write enable signal 1057 is enabled, the interface circuit is configured to sequentially read configuration data from multiple data registers of the analog circuit blocks and write the configuration data to internal memory (here, an NVM, but of course other types of internal memory may be used). In one embodiment, the NVM write procedure 1000 is configured to read all the configuration data in each of the data registers of each of the analog circuit blocks and write the configuration data to the NVM. However, a subset of the data registers may also be read during the NVM write procedure 1000 in any order.

Similar to the read procedure 800, a specific analog circuit block is selected by asserting at most N block selection signals at an analog circuit block selection output of the interface circuit coupled to each of the N analog circuit blocks. For the first two configuration data shown, the base 2 block address that is asserted as block selection signal 1032 is 1110 or n=14 and is changed (e.g., advanced) to 1111 or n=15 for the last three (shown) configuration data. For each data register read from during the NVM write procedure 1000, the corresponding analog circuit block makes the configuration data available at a data output of the analog circuit block (e.g., at a tristate buffer). The first configuration data read from the X-2^{th} data register of the N-2^{th} analog circuit block shown here as configuration data 0xC4 at N-2 block output 1054).

Data registers are selected from the set of X data registers corresponding to the currently selected analog circuit block (or less than X if the currently selected analog circuit block has less than the maximum number of data registers) by asserting at most X block selection signals at a register selection output of the interface circuit coupled to each of the N analog circuit blocks. Here again, a base 2 address system is used for register selection signal 1034 (which is 0xFE or x=254 for the first configuration data, 0xFF or x=255 for the second configuration data, is set to 0x00 of x=0 for the third configuration data as the selected analog circuit clock is advanced, and then continues from there).

At some point after the NVM write enable signal 1057 is enabled (but before configuration data is needed on the parallel data bus), the data output of the selected analog circuit block (the N-2 block output 1054) is enabled using an N-2 block enable signal 1051 (e.g., en_N-1 is made high) and the configuration data being read from the data register is available on the parallel data bus. When a new analog circuit block is selected (such as advancing to the N-1^{th} analog circuit block), the N-2 block enable signal 1051 is transitioned to a disabled state and the N-1 block output 1055 is enabled using an N-1 block enable signal 1053. As before, the interface enable signal 1052 and the enable signals of the unselected analog circuit blocks remain in the disabled state (e.g., logical ‘0’) so that the data output 1048 of the interface circuit and the data outputs of the unselected analog circuit blocks stay in the high-Z state.

A read enable signal 1037 is then pulsed with appropriate timing to read the configuration data from the currently selected data register of the selected data registers 1056. Once the configuration data is made available to the interface circuit using the read enable signal 1037, the configuration data can be written to the NVM (e.g., using the I2C protocol). The write enable signal 1036 is maintained in the disabled state since configuration data is being read from the data registers.

These steps are repeated as desired to read additional configuration data from additional data registers to will be written to the NVM. Specifically, the steps of selecting an additional data register, transmitting additional configuration data from the additional data register over the parallel data bus to the interface circuit, and writing the additional configuration data into the NVM may be repeated by successively pulsing the read enable signal 1037 (as shown) for a currently selected analog circuit block. Then, these steps may all be repeated as desired for additional selected analog circuit blocks.

Example embodiments of the invention are summarized here. Other embodiments can also be understood from the entirety of the specification as well as the claims filed herein.

Example 1. An integrated circuit including: N analog circuit blocks, each including at most X data registers; a bidirectional M-bit parallel data bus coupled to each of the N analog circuit blocks; an external data port configured to receive data external to the integrated circuit; and an interface circuit coupled to the external data port and the bidirectional M-bit parallel data bus, the interface circuit including an analog circuit block selection output coupled to each of the N analog circuit blocks and configured to select an analog circuit block using at most N signals, a register selection output coupled to each of the N analog circuit blocks and configured to select a data register using at most X signals, and a mode selection output coupled to each of the N analog circuit blocks and configured to control the direction of data flow between the N analog circuit blocks and the interface circuit on the bidirectional M-bit parallel data bus.

Example 2. The integrated circuit of example 1, further including: a non-volatile memory (NVM) coupled to the interface circuit and configured to read and write configuration data to and from selected data registers of selected analog circuit blocks over the bidirectional M-bit parallel data bus.

Example 3. The integrated circuit of one of examples 1 and 2, where the register selection output is a log₂X-bit register address coupled to each of the N analog circuit blocks.

Example 4. The integrated circuit of one of examples 1 and 2, where the register selection output includes X signals coupled to each of the N analog circuit blocks, each of the X signals being configured to select one of the at most X data registers of a respective analog circuit block.

Example 5. The integrated circuit of one of examples 1 to 4, where the analog circuit block selection output is a log₂N-bit block address coupled to each of the N analog circuit blocks.

Example 6. The integrated circuit of one of examples 1 to 4, where the analog circuit block selection output includes N signals each coupled to a corresponding analog circuit block, each of the N signals being configured to select one of the N analog circuit blocks.

Example 7. The integrated circuit of one of examples 1 to 6, where the mode selection output consists of a single bit coupled to each of the N analog circuit blocks and configured to toggle the mode of the selected analog circuit block between write mode and read mode.

Example 8. The integrated circuit of one of examples 1 to 6, where the mode selection output includes a write enable signal and a read enable signal both coupled to each of the N analog circuit blocks, the write enable signal being configured to enable write mode of the selected analog circuit block and the read enable signal being configured to enable read mode of the selected analog circuit block.

Example 9. An integrated circuit including: N analog circuit blocks, each including at most X data registers; a bidirectional M-bit parallel data bus coupled to each of the N analog circuit blocks; an external data port configured to receive data external to the integrated circuit; an interface circuit coupled to the external data port and the bidirectional M-bit parallel data bus, the interface circuit including an analog circuit block selection output coupled to each of the N analog circuit blocks and configured to select an analog circuit block using at most N signals, a register selection output coupled to each of the N analog circuit blocks and configured to select a data register using log₂X signals, the register selection output being a log₂X-bit register address coupled to each of the N analog circuit blocks, and a mode selection output coupled to each of the N analog circuit blocks and configured to control the direction of data flow between the N analog circuit blocks and the interface circuit on the bidirectional M-bit parallel data bus; and an NVM coupled to the interface circuit and configured to read and write configuration data to and from selected data registers of selected analog circuit blocks over the bidirectional M-bit parallel data bus.

Example 10. The integrated circuit of example 9, where X is 256, the register selection output being an 8-bit register address.

Example 11. The integrated circuit of one of examples 9 and 10, where M is 8, the bidirectional M-bit parallel data bus being an 8-bit parallel data bus.

Example 12. The integrated circuit of one of examples 9 to 11, where the analog circuit block selection output is a log₂N-bit block address coupled to each of the N analog circuit blocks.

Example 13. The integrated circuit of claim 12, wherein N is at most 16, the analog circuit block selection output being a 4-bit block address.

Example 14. The integrated circuit of one of examples 9 to 11, where the analog circuit block selection output includes N signals each coupled to a corresponding analog circuit block, each of the N signals being configured to select one of the N analog circuit blocks.

Example 15. The integrated circuit of one of examples 9 to 14, where the mode selection output consists of a single bit coupled to each of the N analog circuit blocks and configured to toggle the mode of the selected analog circuit block between write mode and read mode.

Example 16. The integrated circuit of one of examples 9 to 14, where the mode selection output includes a write enable signal and a read enable signal both coupled to each of the N analog circuit blocks, the write enable signal being configured to enable write mode of the selected analog circuit block and the read enable signal being configured to enable read mode of the selected analog circuit block.

Example 17. A method of transferring configuration data between an interface circuit of an integrated circuit and a data register of an analog circuit block, the method including: selecting a first analog circuit block from N analog circuit blocks of the integrated circuit by asserting at most N block selection signals at an analog circuit block selection output of the interface circuit coupled to each of the N analog circuit blocks; selecting a first data register from at most X data registers of the first analog circuit block by asserting at most X block selection signals at a register selection output of the interface circuit coupled to each of the N analog circuit blocks; enabling a data output of the interface circuit coupled to a bidirectional M-bit parallel data bus to transmit first configuration data over the bidirectional M-bit parallel data bus to the first analog circuit block, the bidirectional M-bit parallel data bus being coupled to each of the N analog circuit blocks; and writing the first configuration data from the bidirectional M-bit parallel data bus to the first data register by asserting, after enabling the data output of the interface circuit, a write enable signal at a mode selection output of the interface circuit coupled to each of the N analog circuit blocks.

Example 18. The method of example 17, further including: reading the first configuration data from nonvolatile memory of the integrated circuit to receive the first configuration data at the data output of the interface circuit; and repeating the following steps for each additional data register of the first analog circuit block: selecting an additional first data register from the at most X data registers of the first analog circuit block by asserting at most X block selection signals at the register selection output; reading additional first configuration data from the nonvolatile memory; transmitting the additional first configuration data over the bidirectional M-bit parallel data bus to the first analog circuit block; and writing the additional first configuration data in the corresponding additional first data register; and repeating the previous steps for each additional analog circuit block of the N analog circuit blocks.

Example 19. The method of one of examples 17 and 18, further including: selecting a second analog circuit block from the N analog circuit blocks by asserting at most N block selection signals at the analog circuit block selection output; selecting a second data register from the at most X data registers of the second analog circuit block by asserting at most X block selection signals at the register selection output; enabling a data output of the second analog circuit block coupled to the bidirectional M-bit parallel data bus to transmit second configuration data over the bidirectional M-bit parallel data bus to the interface circuit; and reading the second configuration data from the bidirectional M-bit parallel data bus by asserting, after enabling the data output of the second analog circuit block, a read enable signal at the mode selection output.

Example 20. The method of example 19, further including: writing the second configuration data in nonvolatile memory of the integrated circuit; and repeating the following steps for each additional data register of the second analog circuit block: selecting an additional second data register from the at most X data registers of the second analog circuit block by asserting at most X block selection signals at the register selection output; transmitting additional second configuration data from the additional second data register over the bidirectional M-bit parallel data bus to the interface circuit; and writing the additional second configuration data in the nonvolatile memory of the integrated circuit; and repeating the previous steps for each additional analog circuit block of the N analog circuit blocks.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An integrated circuit comprising:
N analog circuit blocks, each comprising at most X data registers;
a bidirectional M-bit parallel data bus coupled to each of the N analog circuit blocks;
an external data port configured to receive data external to the integrated circuit; and
an interface circuit coupled to the external data port and the bidirectional M-bit parallel data bus, the interface circuit comprising
an analog circuit block selection output coupled to each of the N analog circuit blocks and configured to select an analog circuit block using at most N signals,
a register selection output coupled to each of the N analog circuit blocks and configured to select a data register using at most X signals, and
a mode selection output coupled to each of the N analog circuit blocks and configured to control the direction of data flow between the N analog circuit blocks and the interface circuit on the bidirectional M-bit parallel data bus.

2. The integrated circuit of claim 1, further comprising:
a non-volatile memory (NVM) coupled to the interface circuit and configured to read and write configuration data to and from selected data registers of selected analog circuit blocks over the bidirectional M-bit parallel data bus.

3. The integrated circuit of claim 1, wherein the register selection output is a log₂X-bit register address coupled to each of the N analog circuit blocks.

4. The integrated circuit of claim 1, wherein the register selection output comprises X signals coupled to each of the N analog circuit blocks, each of the X signals being configured to select one of the at most X data registers of a respective analog circuit block.

5. The integrated circuit of claim 1, wherein the analog circuit block selection output is a log₂N-bit block address coupled to each of the N analog circuit blocks.

6. The integrated circuit of claim 1, wherein the analog circuit block selection output comprises N signals each coupled to a corresponding analog circuit block, each of the N signals being configured to select one of the N analog circuit blocks.

7. The integrated circuit of claim 1, wherein the mode selection output consists of a single bit coupled to each of the N analog circuit blocks and configured to toggle the mode of the selected analog circuit block between write mode and read mode.

8. The integrated circuit of claim 1, wherein the mode selection output comprises a write enable signal and a read enable signal both coupled to each of the N analog circuit blocks, the write enable signal being configured to enable write mode of the selected analog circuit block and the read enable signal being configured to enable read mode of the selected analog circuit block.

9. An integrated circuit comprising:
N analog circuit blocks, each comprising at most X data registers;
a bidirectional M-bit parallel data bus coupled to each of the N analog circuit blocks;
an external data port configured to receive data external to the integrated circuit;
an interface circuit coupled to the external data port and the bidirectional M-bit parallel data bus, the interface circuit comprising
an analog circuit block selection output coupled to each of the N analog circuit blocks and configured to select an analog circuit block using at most N signals,
a register selection output coupled to each of the N analog circuit blocks and configured to select a data register using log₂X signals, the register selection output being a log₂X-bit register address coupled to each of the N analog circuit blocks, and
a mode selection output coupled to each of the N analog circuit blocks and configured to control the direction of data flow between the N analog circuit blocks and the interface circuit on the bidirectional M-bit parallel data bus; and
a non-volatile memory (NVM) coupled to the interface circuit and configured to read and write configuration data to and from selected data registers of selected analog circuit blocks over the bidirectional M-bit parallel data bus.

10. The integrated circuit of claim 9, wherein X is 256, the register selection output being an 8-bit register address.

11. The integrated circuit of claim 9, wherein M is 8, the bidirectional M-bit parallel data bus being an 8-bit parallel data bus.

12. The integrated circuit of claim 9, wherein the analog circuit block selection output is a log₂N-bit block address coupled to each of the N analog circuit blocks.

13. The integrated circuit of claim 12, wherein N is at most 16, the analog circuit block selection output being a 4-bit block address.

14. The integrated circuit of claim 9, wherein the analog circuit block selection output comprises N signals each coupled to a corresponding analog circuit block, each of the N signals being configured to select one of the N analog circuit blocks.

15. The integrated circuit of claim 9, wherein the mode selection output consists of a single bit coupled to each of the N analog circuit blocks and configured to toggle the mode of the selected analog circuit block between write mode and read mode.

16. The integrated circuit of claim 9, wherein the mode selection output comprises a write enable signal and a read enable signal both coupled to each of the N analog circuit blocks, the write enable signal being configured to enable write mode of the selected analog circuit block and the read enable signal being configured to enable read mode of the selected analog circuit block.

17. A method of transferring configuration data between an interface circuit of an integrated circuit and a data register of an analog circuit block, the method comprising:
selecting a first analog circuit block from N analog circuit blocks of the integrated circuit by asserting at most N block selection signals at an analog circuit block selection output of the interface circuit coupled to each of the N analog circuit blocks;
selecting a first data register from at most X data registers of the first analog circuit block by asserting at most X block selection signals at a register selection output of the interface circuit coupled to each of the N analog circuit blocks;
enabling a data output of the interface circuit coupled to a bidirectional M-bit parallel data bus to transmit first configuration data over the bidirectional M-bit parallel data bus to the first analog circuit block, the bidirectional M-bit parallel data bus being coupled to each of the N analog circuit blocks; and
writing the first configuration data from the bidirectional M-bit parallel data bus to the first data register by asserting, after enabling the data output of the interface circuit, a write enable signal at a mode selection output of the interface circuit coupled to each of the N analog circuit blocks.

18. The method of claim 17, further comprising:
reading the first configuration data from nonvolatile memory of the integrated circuit to receive the first configuration data at the data output of the interface circuit; and
repeating the following steps for each additional data register of the first analog circuit block:
selecting an additional first data register from the at most X data registers of the first analog circuit block by asserting at most X block selection signals at the register selection output;
reading additional first configuration data from the nonvolatile memory;
transmitting the additional first configuration data over the bidirectional M-bit parallel data bus to the first analog circuit block; and
writing the additional first configuration data in the corresponding additional first data register; and
repeating the previous steps for each additional analog circuit block of the N analog circuit blocks.

19. The method of claim 17, further comprising:
selecting a second analog circuit block from the N analog circuit blocks by asserting at most N block selection signals at the analog circuit block selection output;
selecting a second data register from the at most X data registers of the second analog circuit block by asserting at most X block selection signals at the register selection output;
enabling a data output of the second analog circuit block coupled to the bidirectional M-bit parallel data bus to transmit second configuration data over the bidirectional M-bit parallel data bus to the interface circuit; and
reading the second configuration data from the bidirectional M-bit parallel data bus by asserting, after enabling the data output of the second analog circuit block, a read enable signal at the mode selection output.

20. The method of claim 19, further comprising:
writing the second configuration data in nonvolatile memory of the integrated circuit; and
repeating the following steps for each additional data register of the second analog circuit block:
selecting an additional second data register from the at most X data registers of the second analog circuit block by asserting at most X block selection signals at the register selection output;
transmitting additional second configuration data from the additional second data register over the bidirectional M-bit parallel data bus to the interface circuit; and
writing the additional second configuration data in the nonvolatile memory of the integrated circuit; and
repeating the previous steps for each additional analog circuit block of the N analog circuit blocks.
